(19) United States
(12) Patent Application Publication
(10) Pub. No.: US 2024/0282377 A1
(43) Pub. Date: Aug. 22, 2024

(54) NONVOLATILE MEMORY DEVICE AND OPERATING METHOD OF NONVOLATILE MEMORY DEVICE

(71) Applicant: Samsung Electronics Co., Ltd., Suwon-si (KR)

(72) Inventors: Chaehyeon LIM, Suwon-si (KR); Woojae JANG, Suwon-si (KR); Sejun PARK, Suwon-si (KR); Yujeong SEO, Suwon-si (KR); Jaeduk LEE, Suwon-si (KR)

(73) Assignee: Samsung Electronics Co., Ltd., Suwon-si (KR)

(21) Appl. No.: 18/441,331

(22) Filed: Feb. 14, 2024

(30) Foreign Application Priority Data
Feb. 20, 2023 (KR) 10-2023-0022423

(51) Int. Cl. G11C 16/08; G11C 16/04; G11C 16/32

(52) U.S. Cl. CPC G11C 16/08; G11C 16/0433; G11C 16/32

(57) ABSTRACT

Provided is an operating method of a nonvolatile memory device including a plurality of cell strings, each cell string of the plurality of cell strings including a plurality of memory cells, connected between a bit line and a common source line, and vertical holes penetrating a plurality of word lines stacked in a direction perpendicular to a substrate, the operating method including applying a word line voltage to the plurality of word lines, classifying the plurality of word lines into a plurality of regions, each region of the plurality of regions including at least one of the word lines, and recovering voltages of the plurality of word lines by recovering voltages of word lines arranged in a central region among the plurality of regions before recovering voltages of word lines in other regions of the plurality of regions.

### CROSS-REFERENCE TO RELATED APPLICATION

This application is based on and claims priority under 35 U.S.C. § 119 to Korean Patent Application No. 10-2023-0022423, filed on Feb. 20, 2023, in the Korean Intellectual Property Office, the disclosure of which is incorporated by reference herein in its entirety.

### BACKGROUND

The inventive concepts relate to a nonvolatile memory device and an operating method of the nonvolatile memory device.

Memory devices store data under control by a host device, such as a computer, a smartphone, a smart pad, etc. The memory devices include a device that stores data on a magnetic disk, such as a hard disk drive (HDD), and a device that stores data in semiconductor memory, especially non-volatile memory, such as a solid state drive (SSD) card and a memory card.

The nonvolatile memory includes read-only memory (ROM), programmable ROM (PROM), electrically programmable ROM (EPROM), electrically erasable and programmable ROM (EEPROM), flash memory, phase-change RAM (PRAM), magnetic RAM (MRAM), resistive RAM (RRAM), ferroelectric RAM (FRAM), and so on.

Semiconductor manufacturing technology is continuously developed to achieve high integration and high capacity of memory devices. Higher integration of memory devices has an advantage of reducing production costs of memory device. However, due to high integration of memory devices, the scales of the memory devices are reduced and the structures of the memory devices change, which cause various problems to be found. Various new problems may damage data stored in memory devices, and accordingly, the reliability of the memory devices may be reduced.

### SUMMARY

The inventive concepts provide a nonvolatile memory device that sequentially recovers voltages of word lines by classifying regions of a plurality of word lines.

The inventive concepts provide a nonvolatile memory device that classifies regions of a plurality of word lines and first recovers voltages of word lines arranged in a central region.

According to some example embodiments of the inventive concepts, an operating method of a nonvolatile memory device including a plurality of cell strings, each cell string of the plurality of cell strings including a plurality of memory cells, connected between a bit line and a common source line, and vertical holes penetrating a plurality of word lines stacked in a direction perpendicular to a substrate, the operating method including applying a word line voltage to the plurality of word lines, classifying the plurality of word lines into a plurality of regions, each region of the plurality of regions including at least one of the word lines, and recovering voltages of the plurality of word lines by recovering voltages of word lines arranged in a central region among the plurality of regions before recovering voltages of word lines in other regions of the plurality of regions.

According to some example embodiments of the inventive concepts, an operating method of a nonvolatile memory device including a plurality of cell strings, each cell string of the plurality of cell strings including a plurality of memory cells, connected between a bit line and a common source line, and vertical holes penetrating a plurality of word lines stacked in a direction perpendicular to a substrate, the operating method including applying a word line voltage to the plurality of word lines, classifying word lines in a central region among the plurality of word lines into a first region, classifying word lines above the first region into a second region, classifying word lines below the first region into a third region, and recovering voltages of the plurality of word lines by recovering voltages of the word lines in the first region are before recovering voltages of word lines in the second region and the third region.

According to some example embodiments of the inventive concepts, a nonvolatile memory device includes a memory cell array including a plurality of memory blocks, each memory block of the plurality of memory blocks including a plurality of cell strings, each cell string of the plurality of cell strings including a plurality of memory cells connected in series and penetrating at least one string select line, a plurality of word lines, and at least one ground select line having a plate for and stacked on a substrate, an address decoder configured to select a memory block the plurality of memory blocks, and provide driving voltages to the at least one string select line, the plurality of word lines, and a ground select line of the selected memory block, and a control logic configured to control the address decoder during a program operation and a read operation, classify the plurality of word lines into a plurality of regions, and sequentially recover voltages of word lines in a central region of the plurality of regions, voltages of word lines in a region above the central region, and voltages of word lines in a region below the central region.

### BRIEF DESCRIPTION OF THE DRAWINGS

Some example embodiments will be more clearly understood from the following detailed description taken in conjunction with the accompanying drawings in which:

FIG. 1 is a schematic block diagram illustrating a memory system according to some example embodiments;

FIG. 2 is a block diagram illustrating in detail a memory device according to some example embodiments;

FIG. 3 is a perspective view illustrating a first memory block among memory blocks, according to some example embodiments;

FIG. 4 is a circuit diagram illustrating an equivalent circuit of a first memory block among memory blocks of FIG. 2;

FIG. 5 is a flowchart illustrating an operating method of a memory device, according to some example embodiments;

FIG. 6 is a flowchart illustrating a recovery process of a memory device, according to some example embodiments;

FIG. 7 is a schematic diagram illustrating a recovery line of a memory device according to some example embodiments;

FIG. 8 is a graph illustrating voltages of word lines of a memory device according to some example embodiments;

FIG. 9 is a graph illustrating voltages of word lines of a memory device according to some example embodiments;

FIG. 10 is a graph illustrating an effect of a memory device according to some example embodiments; and

FIG. 11 is a graph illustrating an effect of a memory device according to some example embodiments.

### DETAILED DESCRIPTION

Hereinafter, some example embodiments of the inventive concepts are in detail with reference to the accompanying drawings. The same reference numerals are used for the same components in the drawings, and duplicate descriptions thereof are omitted.

When the words “about” and “substantially” are used in this application in connection with a numerical value, it is intended that the associated numerical value include a tolerance of ±10% around the stated numerical value, unless otherwise explicitly defined. Further, regardless of whether numerical values are modified as “about” or “substantially,” it will be understood that these values should be construed as including a of ±10% around the stated numerical value.

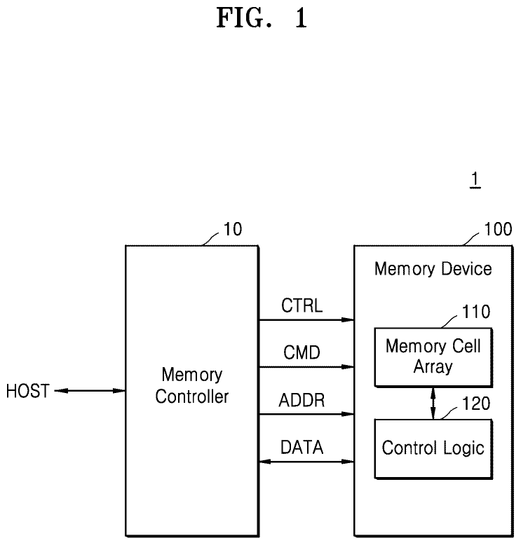

FIG. 1 is a schematic block diagram illustrating a memory system according to some example embodiments.

Referring to FIG. 1, a memory system 1 may include a memory controller 10 and/or a memory device 100, and the memory device 100 may include a memory cell array 110 and/or a control logic 120. Although the embodiment illustrates that the memory system 1 includes many conceptual hardware components, the memory system 1 is not limited thereto and may include other components.

The memory device 100 may include a nonvolatile memory device. In some example embodiments, the memory system 1 may be implemented as an internal memory device embedded in an electronic device. For example, the memory system 1 may be implemented as an embedded universal flash storage (UFS) memory device, an embedded multi-media card (eMMC), and/or a solid state drive (SSD). In some example embodiments, the memory system 1 may be an external memory device removable from an electronic device. For example, the memory system 1 may include at least one of a UFS memory card, a compact flash (CF) card, a secure digital (SD) card, a micro secure digital (Micro-SD) card, a mini secure digital (Mini-SD) card, an extreme digital (xD) card, and/or a memory stick.

The memory controller 10 may control the memory device 100 to read data stored in the memory device 100 or to program data into the memory device 100 in response to a read/write request from a host HOST. Specifically, the memory controller 10 may control a program operation, a read operation, and/or an erase operation of the memory device 100 by providing an address signal ADDR, a command signal CMD, and/or a control signal CTRL to the memory device 100. Also, data DATA to be programmed and read data DATA may be transmitted and received between the memory controller 10 and the memory device 100. Also, the memory device 100 may receive the control signal CTRL through a control line. Also, the memory device 100 may include the memory cell array 110 and/or the control logic 120.

For example, the memory device 100 may be implemented as a single memory chip. In another example, the memory device 100 may be implemented as a plurality of memory chips. One memory chip may be composed of a single die or a plurality of dies. A single die may be composed of a single plane or a plurality of planes. One plane may include a plurality of memory blocks, the memory blocks may each include a plurality of pages, and the pages may each include a plurality of sectors.

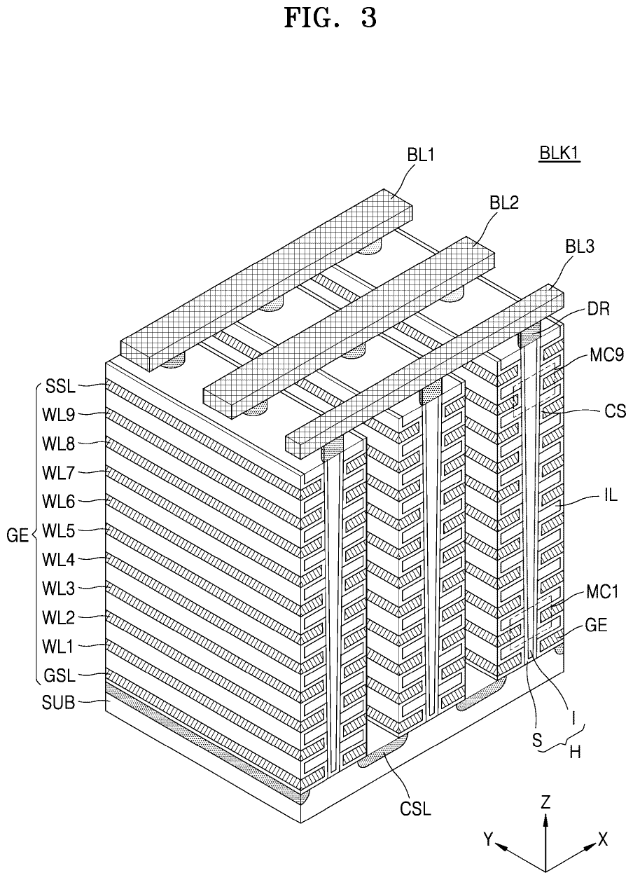

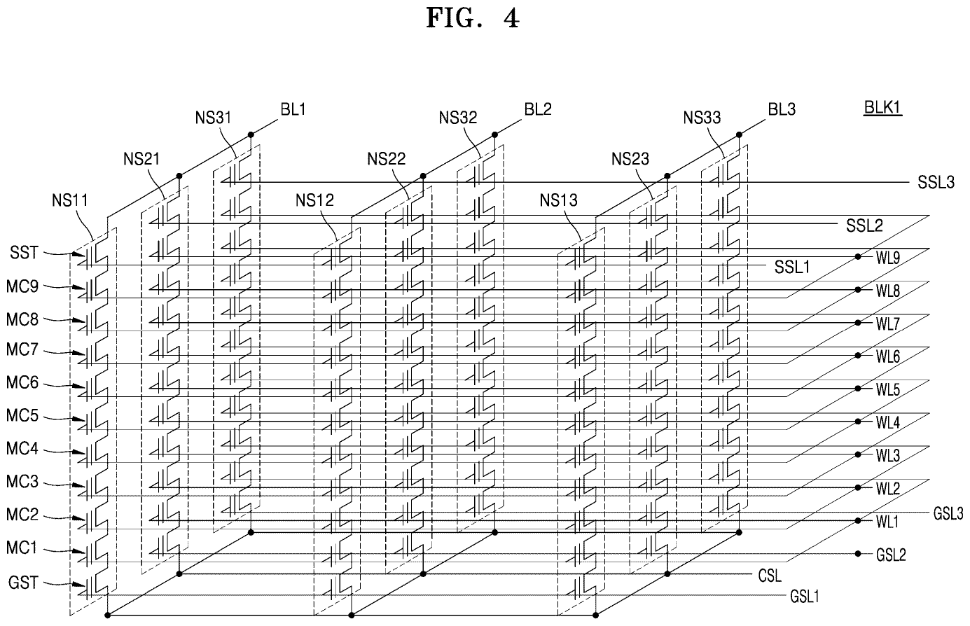

The memory cell array 110 may include a plurality of memory blocks, the plurality of memory blocks may each include a plurality of memory cells, and the plurality of memory cells may include, for example, a plurality of flash memory cells. Hereinafter, some example embodiments are described in detail by taking a case where a plurality of memory cells are, for example, a plurality of NAND flash memory cells. The memory cell array 110 may include a three-dimensional memory cell array including a plurality of cell strings, which are described in detail with reference to FIGS. 3 and 4.

The three-dimensional memory cell array may be formed monolithically in an active region on a substrate, such as a silicon substrate, and in at least one physical level of a plurality of memory cell arrays including a circuit that is associated with operations of the plurality of memory cells and formed on or in a substrate. The “monolithic form” indicates that layers of levels of an array are stacked directly on layers of lower level of the array. In some example embodiments according to the inventive concepts, a three-dimensional memory cell array may include cell strings arranged in the vertical direction such that at least one memory cell is on another memory cell. The at least one memory cell may include a charge trap layer.

The control logic 120 may perform a program operation such that threshold voltages of memory cells of a certain page adjacent to the same position from a substrate of the three-dimensional memory cell array (the memory cell array 110) have a plurality of target states according to a program command from the memory controller 10. The program operation may be performed by program loops based on a voltage increase of the program voltage, and each of the program loops may include a program section and/or a verification section. The control logic 120 may perform a read operation on a selected memory cell from among memory cells included in the three-dimensional memory cell array 110 according to a read command from the memory controller 10.

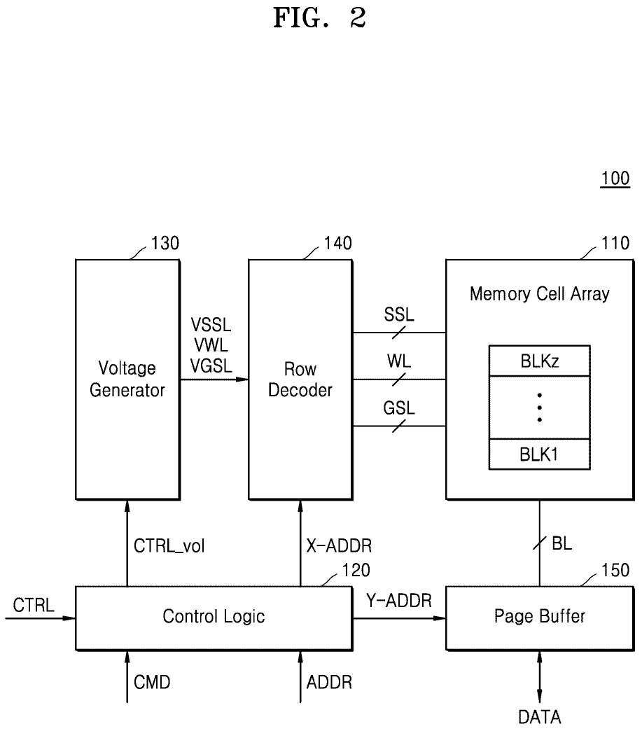

FIG. 2 is a block diagram illustrating in detail a memory device according to some example embodiments.

FIG. 2 may show, for example, an example embodiment of the memory device 100 of FIG. 1. FIG. 2 illustrates a schematic configuration of a flash memory device. The configuration of the flash memory device illustrated in FIG. 2 is an example and is not a configuration of an actual flash memory device. Also, an example of the configuration of the flash memory device illustrated in FIG. 2 does not represent or suggest limitations to the inventive concepts. For the sake of convenience of description, the memory device 100 may be referred to as a flash memory device.

Referring to FIG. 2, the memory device 100 may include a memory cell array 110, a control logic 120, a voltage generator 130, a row decoder 140, and/or a page buffer 150. Although not illustrated in FIG. 2, the memory device 100 may further include various other components related to a memory operation of, for example, a data input/output circuit and/or an input/output interface.

The memory cell array 110 may include a plurality of memory cells and may be connected to a plurality of word lines WL, a plurality of string select lines SSL, a plurality of ground select lines GSL, a plurality of common source lines CSL, and/or a plurality of bit lines BL. The memory cell array 110 may be connected to the row decoder 140 through the plurality of word lines WL, the plurality of string select lines SSL, and/or the plurality of ground select lines GSL and may be connected to the page buffer 150 through the plurality of bit lines BL.

For example, a plurality of memory cells included in the memory cell array 110 may be composed of a plurality of nonvolatile memory cells that maintain stored data even when power thereto is disconnected. Specifically, when the plurality of memory cells are a plurality of nonvolatile memory cells, the memory device 100 may be composed of electrically erasable programmable read-only memory (EEPROM), flash memory, phase-change random access memory (PRAM), resistance random access memory (RRAM), nano floating gate memory (NFGM), polymer random access memory (PoRAM), magnetic random access memory (MRAM), ferroelectric random access memory (FRAM), or so on. Hereinafter, although embodiments are described by taking a case where a plurality of memory cells are a plurality of NAND flash memory cells as an example, the inventive concepts are not limited thereto.

The memory cell array 110 may include a plurality of memory blocks BLK1 to BLKz, and the plurality of memory block BLK1 to BLKz may each have a planar structure or a three-dimensional structure. The memory cell array 110 may include at least one of a single-level cell (SLC) block including single-level cells, a multi-level cell (MLC) block including multi-level cells, a triple-level cell (TLC) block including triple-level cells, and/or a quad-level cell (QLC) block including quad-level cells. For example, some of the plurality of memory blocks BLK1 to BLKz may be composed of the SLC block and the others may be composed of MLC blocks, TLC blocks, or QLC blocks.

The control logic 120 may output various internal control signals for programming data into the memory cell array 110 and/or for reading data from the memory cell array 110 based on the command signal CMD, the address signal ADDR, and/or the control signal CTRL received from the memory controller 10. For example, the control logic 120 may output a voltage control signal CTRL_vol for controlling levels of various voltages generated by the voltage generator 130. The control logic 120 may provide a row address signal X-ADDR to the row decoder 140 and/or provide a column address signal Y-ADDR to the page buffer 150.

The voltage generator 130 may generate various voltages for performing a program operation, a read operation, and/or an erase operation on the memory cell array 110 based on the voltage control signal Ctrl_vol. The voltage generator 130 may generate various voltages used in the memory device 100 and generate, for example, a word line voltage VWL, a string select line voltage VSSL, and/or a ground select line voltage VGSL. For example, the voltage generator 130 may generate a program voltage, a verification voltage, a read voltage, a pass voltage, an erase voltage, an erase verification voltage, and so on.

The row decoder 140 may be connected to the memory cell array 110 through a plurality of string select lines SSL, a plurality of word lines WL, and/or a plurality of ground select lines GSL. During the program operation and/or the read operation, the row decoder 140 may select at least one of the plurality of word lines WL of a selected memory block in response to the row address signal X-ADDR. During the program operation, the row decoder 140 may provide the word line WL of a selected memory cell with a program voltage as the word line voltage VWL in response to the row address signal X-ADDR and provide the word lines WL of non-selected memory cells with a pass voltage as the word line voltage VWL.

The page buffer 150 may operate as a write driver and/or a sense amplifier. During the program operation, the page buffer 150 may operate as a write driver to apply, to the bit line BL, a voltage according to data DATA to be stored in the memory cell array 110. In addition, during the read operation, the page buffer 150 operates as a sense amplifier to sense the data DATA stored in the memory cell array 110.

FIG. 3 is a perspective view illustrating the first memory block BLK1 among the plurality of memory blocks BLK1 to BLKz according to the some example embodiments.

Referring to FIG. 3, the first memory block BLK1 may be formed in a direction perpendicular to a substrate SUB. The first memory block BLK1 may include NAND strings and/or cell strings formed in a three-dimensional structure and/or a vertical structure. The first memory block BLK1 includes structures extending in directions X, Y, and Z.

Although FIG. 3 illustrates that the first memory block BLK1 includes a ground select line GSL, a string select line SSL, nine word lines WL1 to WL9, and three bit lines BL1 to BL3, the first memory block BLK1 is not limited thereto and may actually include more or less lines than these.

The first memory block BLK1 may be formed in a direction perpendicular to the substrate SUB (the Z direction). The substrate SUB may have a first conductivity type (for example, p type), and a common source line CSL doped with an impurity of a second conductivity type (for example, n type) may be formed in the substrate SUB.

For example, the substrate SUB may include a bulk silicon substrate, a silicon on insulator (SOI) substrate, a germanium substrate, a germanium on insulator (GOI) substrate, a silicon-germanium substrate, and/or a substrate of an epitaxial thin film formed by performing a selective epitaxial growth (SEG). The substrate SUB may be formed of at least one of semiconductor materials, such as silicon (Si), germanium (Ge), silicon germanium (SiGe), gallium arsenide (GaAs), indium gallium arsenide (InGaAs), aluminum gallium arsenide (AlGaAs)), and/or a mixture thereof.

Common source lines CSL, each extending in a first direction (the Y direction) and doped with an impurity of the second conductivity type (for example, n type), may be provided to the substrate SUB. A plurality of insulating layers IL extending in the first direction (the Y direction) may be sequentially provided in the third direction (the Z direction) over regions of the substrate SUB between two adjacent common source lines CSL, and the plurality of insulating layers IL may be separated from each other by a preset (or alternately given) distance in the third direction (the Z direction). For example, the plurality of insulating layers IL may be formed of an insulating material, such as silicon oxide.

A plurality of vertical holes H, which are sequentially arranged in the first direction (the Y direction) and penetrate the plurality of insulating layers IL in the third direction (the Z direction), may be provided over regions of the substrate SUB between two adjacent common source lines CSL. For example, the plurality of vertical holes H may penetrate the plurality of insulating layers IL and contact the substrate SUB. Specifically, a surface layer S of each, or one or more, of the plurality of vertical holes H may be formed of a silicon material doped with the first conductivity type and may function as a channel region. In addition, an internal layer I of each, or one or more, of the plurality of vertical holes H may be formed of an insulating material, such as silicon oxide, or may include an air gap.

In a region between two adjacent common source lines CSL, a charge storage layer CS may be provided along the plurality of insulating layers IL, the vertical hole H, and/or an exposed surface of the substrate SUB. The charge storage layer CS may include a gate insulating layer (or a “tunneling insulating layer”), a charge trap layer, and/or a blocking insulating layer. For example, the charge storage layer CS may have an oxide-nitride-oxide (ONO) structure. Also, a gate electrode GE, which includes the ground select line GSL, the string select line SSL, and/or the plurality of word lines WL1 to WL9, may be provided on an exposed surface of the charge storage layer CS in a region between two adjacent common source lines CSL.

Drains and/or drain contacts DR may be respectively provided on the plurality of vertical holes H. For example, the drains and/or drain contacts DR may each be formed of a silicon material doped with an impurity of the second conductivity type. The plurality of bit lines BL1 to BL3 extending in a second direction (the X direction) and separated from each other by a preset (or alternately given) distance in the first direction (the Y direction) may be provided on the drains and/or drain contacts DR.

FIG. 4 is a circuit diagram illustrating an equivalent circuit of the first memory block BLK1 among the plurality of memory blocks BLK1 to BLKz of FIG. 2.

Referring to FIG. 4, the first memory block BLK1 may be implemented as NAND flash memory having a vertical structure, and each, or one or more, of the plurality of memory blocks BLK1 to BLKz illustrated in FIG. 2 may be implemented as illustrated in FIG. 4.

The first memory block BLK1 may include a plurality of NAND cell strings NS11 to NS33, a plurality of word lines WL1 to WL9, a plurality of bit lines BL1 to BL3, and/or a plurality of ground select lines GSL1 to GSL3, a plurality of string select lines SSL1 to SSL3, and/or a common source line CSL. Here, the number of NAND cell strings NS11 to NS33, the number of word lines WL1 to WL9, the number of bit lines BL1 to BL3, and/or the number of ground select lines GSL1 to GSL3, the number of string select lines SSL1 to SSL3 may be variously changed depending on embodiments.

The NAND cell strings NS11, NS21, and/or NS31 may be provided between the first bit line BL1 and the common source line CSL, the NAND cell strings NS12, NS22, and/or NS32 may be provided between the second bit line BL2 and the common source line CSL, and the NAND cell strings NS13, NS23, and/or NS33 may be provided between the third bit line BL3 and the common source line CSL. Each, or one or more, NAND cell string (for example, NS11) may include a string select transistor SST, a plurality of memory cells MC1 to MC9, and/or a ground select transistor GST connected to each other in series.

NAND cell strings commonly connected to one bit line may constitute one column. For example, the NAND cell strings NS11, NS21, and NS31 commonly connected to the first bit line BL1 may correspond to a first column, the NAND cell strings NS12, NS22, and NS32 commonly connected to the second bit line BL2 may correspond to a second column, and the NAND cell strings NS13, NS23, and NS33 commonly connected to the third bit line BL3 may correspond to a third column.

NAND cell strings connected to one string select line may constitute one row. For example, the NAND cell strings NS11, NS12, and/or NS13 connected to the first string select line SSL1 may correspond to a first row, the NAND cell strings NS21, NS22, and/or NS23 connected to the second string select line SSL2 may correspond to a second row, and the NAND cell strings NS31, NS32, and/or NS33 connected to the third string select line SSL3 may correspond to a third row.

A plurality of string select transistors SST may each be connected to the corresponding string select line SSL1 or SSL3. The plurality of memory cells MC1 to MC9 may be respectively connected to corresponding word lines WL1 to WL9. A plurality of ground select transistors GST may each be connected to a corresponding ground select line GSL1 or GSL3, and the plurality of string select transistors SST may each be connected to a corresponding bit line BL1 or BL3. A plurality of ground select transistors GST may be connected to the common source line CSL.

In some example embodiments, word lines (for example, WL1) in the same height may be connected in common, the plurality of string select lines SSL1 to SSL3 in the same height may be separated from each other, and the plurality of ground select lines GSL1 to GSL3 in the same height may also be separated from each other. For example, when programming memory cells connected to the first word line WL1 and included in the NAND cell strings NS11, NS12, and/or NS13 corresponding to the first column, the first word line WL1 and the first string select line SSL1 may be selected. However, the inventive concepts are not limited thereto, and in another example embodiment, the ground select lines GSL1 to GSL3 may be connected in common.

Each, or one or more, cell string may include one or more dummy memory cells between the string select transistor SST and the plurality of memory cells MC depending on example embodiments. Each, or one or more, cell string may include one or more dummy memory cells between the ground select transistor GST and the plurality of memory cells MC. Each, or one or more, cell string may include one or more dummy memory cells between plurality of memory cells MC. The dummy memory cells may have the same structure as the plurality of memory cells MC and may be non-programmed (for example, program-inhibited) or programmed differently from the plurality of memory cells MC. For example, when the plurality of memory cells MC are programmed to have two or more threshold voltage distributions, the dummy memory cells may be programmed to have one threshold voltage distribution range or fewer threshold voltage distributions than plurality of memory cells MC.

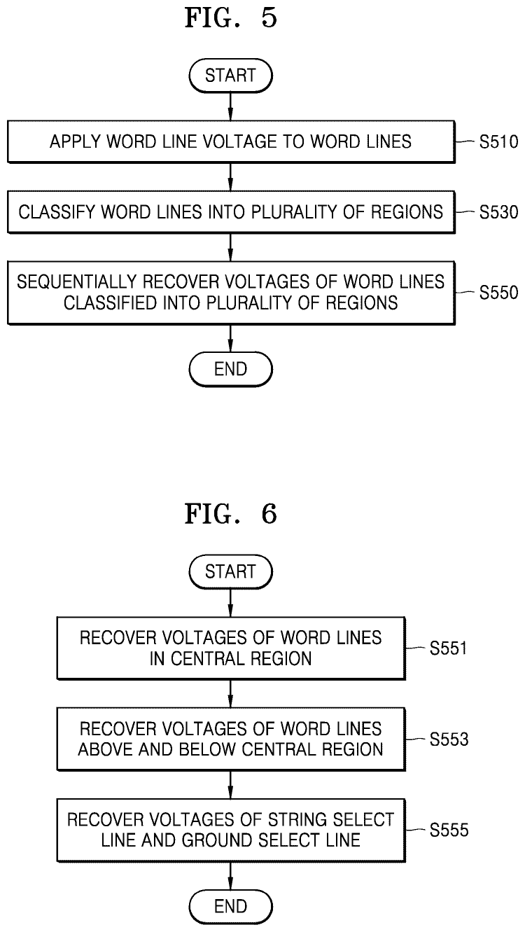

FIG. 5 is a flowchart illustrating an operating method of the memory device 100, according to some example embodiments.

Referring to FIG. 5, the operating method of the memory device 100 according to some example embodiments may include an operation of applying the word line voltage VWL to the plurality of word lines WL (S510).

The voltage generator 130 may generate various voltages for performing a program operation, a read operation, and/or an erase operation on the memory cell array 110 based on the voltage control signal Ctrl_vol. The voltage generator 130 may generate various voltages used by the memory device 100 and generate, for example, a word line voltage VWL required, or sufficient, for a program operation, a write operation, an erase operation, and so on.

For example, an operation of applying the word line voltage VWL to the plurality of word lines WL may include an operation of applying a program voltage to a selected word line during the program operation. Also, the operation of applying the word line voltage VWL to the plurality of word lines WL may include an operation of applying a read voltage to a selected word line during the read operation.

The operating method of the memory device 100 may include an operation of classifying the plurality of word lines WL into a plurality of regions (S530). The control logic 120 may classify the plurality of word lines WL vertically stacked on the substrate SUB into a plurality of regions.

For example, the control logic 120 may classify the plurality of word lines WL in a central region among the plurality of word lines WL into a first region, the plurality of word lines WL arranged above the first region into a second region, and the plurality of word lines WL arranged below the first region into a third region. However, the inventive concepts are not limited thereto, and the operation of classifying the plurality of word lines WL into one or more regions may include an operation of classifying the plurality of word lines WL into three or more regions.

Each, or one or more, of the first to third regions may include one or more word lines WL. For example, each, or one or more, of the first to third regions may include three word lines WL but the example embodiments are not limited thereto. Also, the first to third regions may include a different number of word lines WL.

The operating method of the memory device 100 may include an operation of sequentially recovering voltages of the plurality of word lines WL classified into a plurality of regions (S550).

The memory device 100 according to the embodiment may first recover voltages of the word lines arranged in the central region among the plurality of word lines WL. The control logic 120 may sequentially recover voltages of the word lines WL in a central region and voltages of the word lines WL above and below the central region.

For example, voltages of the word lines WL of the first region arranged in the central region among the plurality of word lines WL may be first recovered. After the voltages of the word lines WL in the first region are recovered, voltages of the word lines WL in the second and third regions may be recovered. In this case, the voltages of the word lines WL in the second and third regions may be recovered simultaneously.

According to some example embodiments, the control logic 120 may classify the plurality of word lines WL into five regions. The plurality of word lines WL arranged above the second region may be classified as a fourth region, and the plurality of word lines WL arranged below the third region may be classified as a fifth region. After the voltages of the word lines WL in the second and third regions are recovered, the voltages of the word lines WL in the fourth and fifth regions may be recovered. In this case, the voltages of the word lines WL in the fourth region and the fifth region may be recovered simultaneously. For the sake of convenience of description, the present example embodiment describes that the plurality of word lines WL are classified into three regions.

According to the example embodiment, the plurality of word lines WL stacked in a direction perpendicular to the substrate SUB are classified into a plurality of regions and voltages of the word lines WL arranged in a central region are first recovered, and thus, the recovery efficiency of the word lines WL arranged in the central region may be increased.

FIG. 6 is a flowchart illustrating a recovery process of the memory device 100, according to some example embodiments.

Referring to FIG. 6, the recovery method of the memory device 100 according to some example embodiments may include an operation of recovering voltages of the word lines WL arranged in a central region (S551). In this case, the central region may be in the center among regions obtained by vertically classifying the plurality of word lines WL into three regions. Here, the inventive concepts are not limited thereto, and the three regions may include a different number of word lines WL.

The control logic 120 may first recover voltages of the word lines WL arranged in the central region among the plurality of word lines WL. The control logic 120 may apply a recovery voltage to the word lines WL in a first region arranged in the central region. In this case, the recovery voltage may be a power supply voltage VDD.

The recovery method of the memory device 100 may include an operation of recovering voltages of the word lines WL in an upper region and a lower region (S553). The control logic 120 may first recover voltages of the word lines WL arranged in a first region among the plurality of word lines WL, and then recover voltages of the word lines WL arranged in a second region and a third region. The control logic 120 may apply a recovery voltage to the word lines WL in the second region and the third region arranged in the upper region and the lower region. In this case, the recovery voltage may be the power supply voltage VDD.

The recovery method of the memory device 100 may include an operation of recovering voltages of the string select line SSL and the ground select line GSL (S555). The control logic 120 may recover voltages of the string select line SSL and the ground select line GSL after recovering the voltages of the word lines WL arranged in the upper region and the lower region. The control logic 120 may apply a recovery voltage to the string select line SSL and the ground select line GSL. In this case, the recovery voltage may be the power supply voltage VDD.

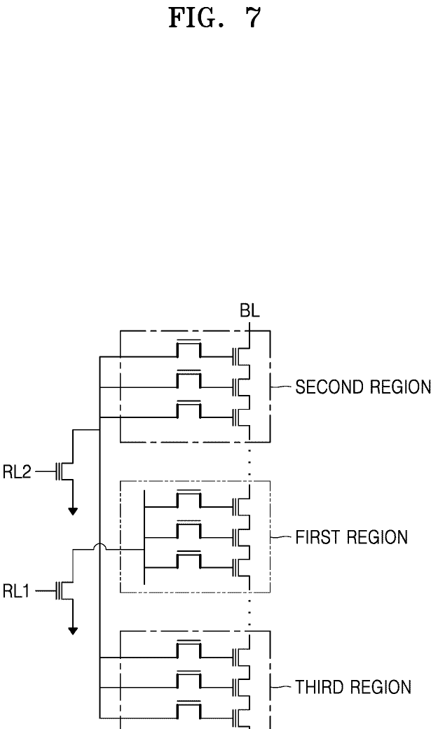

FIG. 7 is a schematic diagram illustrating a recovery line of a memory device according to some example embodiments.

Referring to FIG. 7, the memory device 100 according to some example embodiments may include a plurality of recovery lines RL1 and/or RL2. A circuit may be configured to distinguish recovery lines of the word lines WL in the first region from recovery lines of the word lines WL in the second and third regions. Accordingly, recovery points in time of the word lines WL in the first region may be different from recovery points in time of the word lines WL in the second and third regions.

For example, the first recovery line RL1 may be connected to the word lines WL in the first region. The second recovery line RL2 may be connected to the word lines WL in the second and third regions. However, the inventive concepts are not limited thereto, and the second region and the third region may be connected to different recovery lines.

The control logic 120 may first recover voltages of the word lines WL in the first region through the first recovery line RL1. The control logic 120 may recover voltages of the word lines WL in the second and third regions through the second recovery line RL2. The control logic 120 may apply a recovery voltage to the first recovery line RL1 and then apply another recovery voltage to the second recovery line RL2. A point in time at which the control logic 120 applies another recovery voltage to the second recovery line RL2 may be delayed for a preset (or alternately given) time from a point in time at which a recovery voltage is applied to the first recovery line RL1.

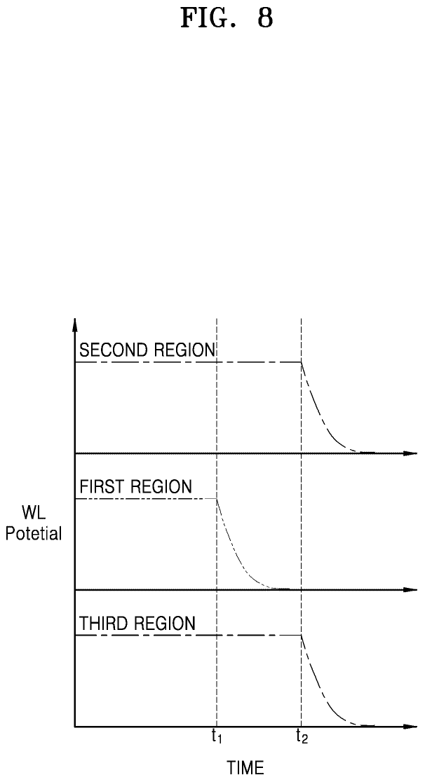

FIG. 8 is a graph illustrating voltages of word lines of a memory device according to some example embodiments.

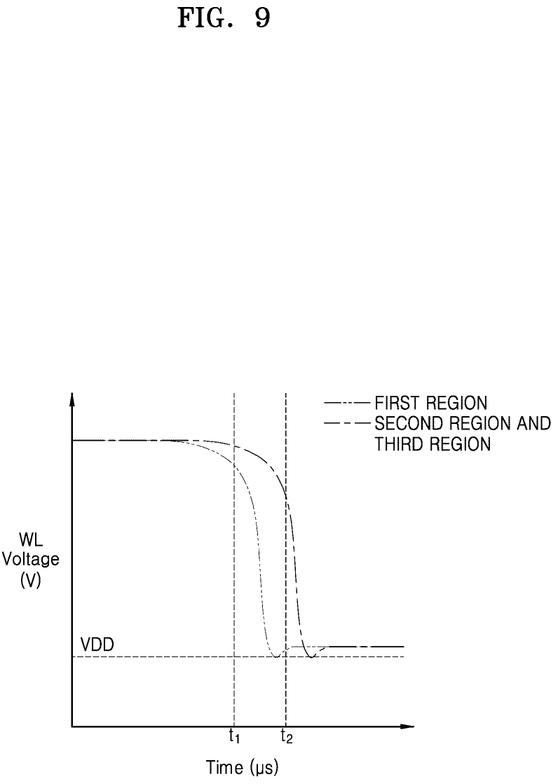

FIG. 9 is a graph illustrating voltages of word lines of a memory device according to some example embodiments.

Referring to FIGS. 8 and 9, in the memory device 100 according to some example embodiments, a recovery point in time of the word lines WL in the first region may be different from a recovery point in time of the word lines WL in the second and third regions.

The word lines WL in the first region may be first recovered through the first recovery line RL1. A recovery voltage may be applied to the word lines WL in the first region at a first point in time t1. The word lines WL in the second and third regions may be recovered through the second recovery line RL2. A recovery voltage may be simultaneously applied to the word lines WL in the second and third regions at a second point in time t2. In this case, the recovery voltage may be the power supply voltage VDD.

While voltages of the word lines WL in the first region are recovered, voltages of the word lines WL in the second and third regions may be delayed for a preset (or alternately given) time. For example, the point in time t2 at which the recovery voltage is applied to the second recovery line RL2 may be delayed by about 25 ms from the point in time t1 at which the recovery voltage is applied to the first recovery line RL1. The time difference between the first point in time t1 and the second point in time t2 may be about 25 ms, but the time difference is not limited thereto.

The recovery of the voltages of the word lines WL in the second and third regions may be performed after the recovery of the voltages of the word lines WL in the first region is completed. However, the inventive concepts are not limited thereto, and the recovery of the voltages of the word lines WL in the second and third regions may be performed during the recovery of the voltages of the word lines WL in the first region.

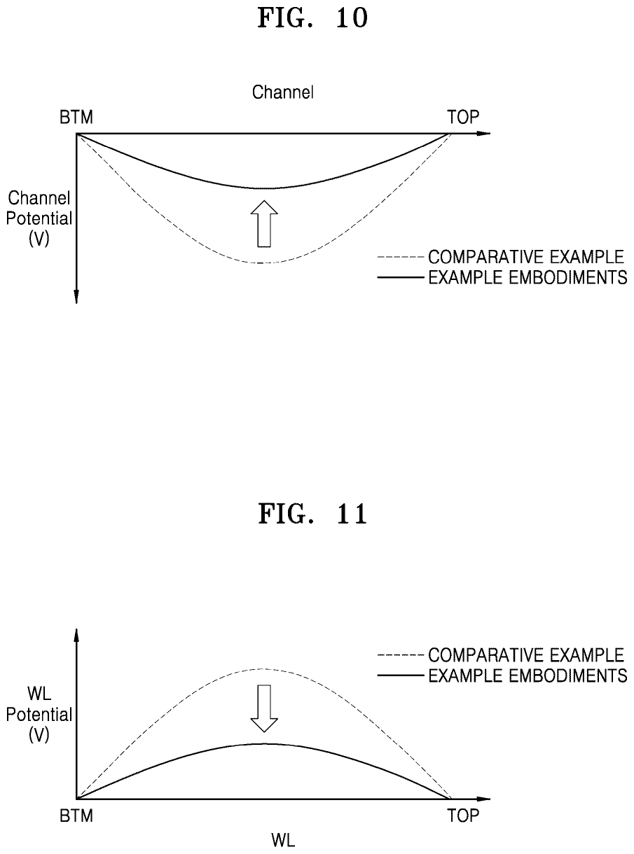

FIG. 10 is a graph illustrating an effect of a memory device according to some example embodiments.

FIG. 11 is a graph illustrating an effect of a memory device according to some example embodiments.

Referring to FIGS. 10 and 11, there is an effect that the memory device 100 according to some example embodiments may increase the recovery efficiency of the word lines WL arranged in a central region compared to a memory device according to a comparative example.

When the memory device 100 is recovered, a ground voltage may be applied to the string select line SSL and the ground select line GSL. Accordingly, electric charges may remain in the charge storage layer CS adjacent to the word lines WL stacked in a direction perpendicular to the substrate SUB to maintain a high channel potential.

In particular, referring to FIG. 10, when the memory device 100 is recovered, channels of the word lines WL in the central region may be floated. When the channels of the word lines WL remain in a floating state and voltages of the word lines WL are recovered, channels of the interrupted word lines WL may be nega-boosted.

Accordingly, referring to FIG. 11, the channels of the word lines WL in the central region may be coupled down by a large amount, and thus, the potential of the word lines WL after recovery may be maintained high. As a residual voltages of the word lines WL increase, the charge retention characteristics of the charge storage layer CS may degrade.

Therefore, according to some example embodiments, the plurality of word lines WL stacked in a direction perpendicular to the substrate SUB are classified into a plurality of regions, and voltages of the word lines WL arranged in a central region are first recovered, and accordingly, there is an effect of increasing the recovery efficiency of the word lines WL arranged in the central region. By first recovering the voltages of the word lines WL arranged in the central region, the channel potential of the word lines WL arranged in the central region may be lowered compared to the comparative example. Accordingly, there is an effect of reducing degradation of charge retention characteristics due to residual voltages of the word lines WL.

By increasing the recovery efficiency of the word lines WL arranged in the central region, charge gain characteristics and charge loss characteristics of the charge storage layer CS may be improved. As a result, the data reliability of the memory device 100 may be increased by increasing the recovery efficiency of the word lines WL arranged in a central region.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to some example embodiments thereof, it will be understood that various changes in form and details may be made therein without departing from the spirit and scope of the following claims.

What is claimed is:

1. An operating method of a nonvolatile memory device including a plurality of cell strings, each cell string of the plurality of cell strings including a plurality of memory cells, connected between a bit line and a common source line, and vertical holes penetrating a plurality of word lines stacked in a direction perpendicular to a substrate, the operating method comprising:
applying a word line voltage to the plurality of word lines;
classifying the plurality of word lines into a plurality of regions, each region of the plurality of regions including at least one of the word lines; and
recovering voltages of the plurality of word lines by recovering voltages of word lines arranged in a central region among the plurality of regions before recovering voltages of word lines in other regions of the plurality of regions.

2. The operating method of claim 1, wherein the classifying of the plurality of word lines comprises:
classifying the word lines in the central region of the plurality of regions into a first region;
classifying word lines above the first region into a second region; and
classifying word lines below the first region into a third region.

3. The operating method of claim 2, wherein the recovering the voltages of the plurality of word lines comprises:
recovering voltages of word lines in the second region and the third region after a delayed amount of time while voltages of word lines in the first region are recovered.

4. The operating method of claim 2, wherein the recovering the voltages of the plurality of word lines comprises:
recovering voltages of the word lines in the first region; and
recovering voltages of the word lines in the second region and the third region.

5. The operating method of claim 4, wherein the recovering the voltages of the plurality of word lines comprises:
simultaneously recovering the voltages of the word lines in the second region and the third region.

6. The operating method of claim 2, wherein
the word lines in the first region are connected to a first recovery line, and
the word lines in the second region and the third region are connected to a second recovery line.

7. The operating method of claim 1, wherein
the plurality of cell strings are in rows and columns on the substrate,
string select transistors of cell strings in one row are commonly connected to a string select line,
ground select transistors of cell strings of two or more rows are commonly connected to a ground select line, and
memory cells of the plurality of cell strings at the same height from the substrate are commonly connected to one of the plurality of word lines.

8. The operating method of claim 7, further comprising:
recovering a voltage of the string select line and a voltage of the ground select line.

9. The operating method of claim 8, wherein the recovering the voltage of the string select line and the voltage of the ground select line comprises:
simultaneously recovering the voltage of the string select line and the voltage of the ground select.

10. The operating method of claim 1, wherein the plurality of regions include a different number of word lines.

11. The operating method of claim 1, wherein the recovering the voltages of the plurality of word lines comprises:
recovering the voltages of the plurality of word lines using a power supply voltage.

12. An operating method of a nonvolatile memory device including a plurality of cell strings, each cell string of the plurality of cell strings including a plurality of memory cells, connected between a bit line and a common source line, and vertical holes penetrating a plurality of word lines stacked in a direction perpendicular to a substrate, the operating method comprising:
applying a word line voltage to the plurality of word lines;
classifying word lines in a central region among the plurality of word lines into a first region;
classifying word lines above the first region into a second region;
classifying word lines below the first region into a third region; and
recovering voltages of the plurality of word lines by recovering voltages of the word lines in the first region are before recovering voltages of word lines in the second region and the third region.

13. The operating method of claim 12, wherein the recovering the voltages of the plurality of word lines comprises:
recovering the voltages of the word lines in the second region and the third after a delayed amount of time while the voltages of the word lines in the first region are recovered.

14. The operating method of claim 12, wherein the recovering the voltages of the plurality of word lines comprises:
simultaneously recovering the voltages of the word lines in the second region and the third region.

15. The operating method of claim 12, wherein
the word lines in the first region are connected to a first recovery line, and
the word lines in the second region and the third region are connected to a second recovery line.

16. The operating method of claim 12, further comprising:
classifying the word lines above the second region into a fourth region; and
classifying the word lines below the third region into a fifth region.

17. The operating method of claim 16, wherein the recovering the voltages of the plurality of word lines comprises:
recovering the voltages of the word lines in the second region and the third region; and
recovering voltages of the word lines in the fourth region and the fifth region.

18. A nonvolatile memory device comprising:
a memory cell array including
a plurality of memory blocks, each memory block of the plurality of memory blocks including a plurality of cell strings, each cell string of the plurality of cell strings including a plurality of memory cells connected in series and penetrating at least one string select line,
a plurality of word lines, and
at least one ground select line having a plate form and stacked on a substrate;
an address decoder configured to
select a memory block of the plurality of memory blocks, and
provide driving voltages to the at least one string select line, the plurality of word lines, and a ground select line of the selected memory block; and
a control logic configured to
control the address decoder during a program operation and a read operation,
classify the plurality of word lines into a plurality of regions, and
sequentially recover voltages of word lines in a central region of the plurality of regions, voltages of word lines in a region above the central region, and voltages of word lines in a region below the central region.

19. The nonvolatile memory device of claim 18, wherein the control logic is configured to
classify the word lines in the central region into a first region,
classify the word lines in the region above the central region into a second region, and
classify the word lines in the region below the central region into a third region.

20. The nonvolatile memory device of claim 19, further comprising:
a first recovery line connected to the word lines in the first region; and
a second recovery line connected to the word lines in the second region and the third region.
